(19) United States
(12) Patent Application Publication
(10) Pub. No.: US 2009/0305497 A1
(43) Pub. Date: Dec. 10, 2009

(54) METHOD FOR FABRICATING SEMICONDUCTOR DEVICE

(76) Inventor: Mitsuhiro OMURA, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/425,789

(22) Filed: Apr. 17, 2009

(30) Foreign Application Priority Data
Jun. 5, 2008 (JP) 2008-147882

(51) Int. Cl. H01L 21/3205; H01L 21/302

(52) U.S. Cl. 438/625; 438/703; 257/E21.297; 257/E21.214

(57) ABSTRACT

A method for fabricating a semiconductor device, includes: forming a first film pattern above a substrate; forming a plurality of second film patterns like sandwiching the first film pattern from both sides; forming a third film in such a way that an upper surface of the first film pattern and an upper surface and an exposed side surface of each of the plurality of second film patterns are coated with the third film; removing a portion of the third film until the upper surface of the first film pattern is exposed; removing, by a wet process, the first film pattern exposed after the portion of the third film is removed; and removing a remainder of the third film by a dry process after the first film pattern is removed.

### CROSS-REFERENCE TO RELATED APPLICATION

This application is based upon and claims the benefit of priority from prior Japanese Patent Application No. 2008-147882 filed on Jun. 5, 2008 in Japan, the entire contents of which are incorporated herein by reference.

### BACKGROUND OF THE INVENTION

1. Field of the Invention

The present invention relates to a method for fabricating a semiconductor device and, for example, relates to a method for fabricating a semiconductor device that forms a pattern of dimensions finer than the resolution limit of exposure technology.

2. Related Art

With higher integration and higher performance of semiconductor devices in recent years, the dimensions required for pattern formation are becoming finer each year. In particular, fine line & space patterns are needed in memory devices and the like in which an ever higher degree of integration is achieved, and lithography technology continues technological innovation to realize such patterns. In recent years, however, device requirements have begun to exceed the resolution limit of lithography and super-fine patterns exceeding the resolution limit are in demand. For example, a method shown below has been proposed to form a super-fine pattern exceeding the resolution limit regarding a technology to form a gate wire.

First, a first dielectric film such as a silicon oxide film is deposited on a semiconductor substrate by thermal oxidation treatment or the like. Further, a gate wire material film composed of polysilicon or the like is deposited on the first dielectric film using CVD technology. Next, a second dielectric film such as a silicon oxide film is deposited on the gate wire material film using CVD technology.

Next, an antireflection film to prevent a reflected light from acting on a photo resist and a photo resist are each laminated one by one and lithography technology is used to perform patterning of a line & space pattern on the photo resist. In this case, the ratio of dimensions of the line portion where a photo resist remains and the space portion where a photo resist is removed is 1:1. Subsequently, downflow technology is used to cause the photo resist to recede isotropically to make the ratio of dimensions of the line portion and the space portion 1:3. Using the photo resist as a mask, the antireflection film and second dielectric film are processed by using dry etching technology and the photo resist and antireflection film are removed by using ashing technology. Accordingly, a pattern whose ratio of line & space is 1:3 is formed in the second dielectric film. A third dielectric film such as silicon nitride (SiN) is deposited on the patterned second dielectric film using CVD technology. In this case, the thickness of the deposited third dielectric film is made equal to the line dimension of the patterned second dielectric film.

Next, by using dry etching technology to etch back the third dielectric film until the surface of the second dielectric film is exposed, a sidewall layer made of the third dielectric film is obtained on sidewalls of the second dielectric film. Subsequently, the second dielectric film is removed by using wet etching technology to obtain the third dielectric film with a line & space pattern. In this manner, the pitch of the line & space can be made half that when a line & space pattern is formed on a resist using the lithography technology. Next, using the patterned third dielectric film as a mask, the gate wire material film is etched using dry etching technology. By this etching process, a pattern of gate electrodes whose pitch of line & space is half that when exposed is formed (see Published Japanese Unexamined Patent Application No. 2002-280388).

However, if the above technology is used, there is a problem that when the second dielectric film sandwiched by sidewall layers made of the third dielectric film is removed using wet etching technology, a film pattern of the sidewall layers made of the third dielectric film formed on both sides falls. Here, if a film pattern to be a line portion falls, no line & space pattern can be formed so that no device can be created.

### BRIEF SUMMARY OF THE INVENTION

In accordance with one aspect of the present invention, a method for fabricating a semiconductor device includes: forming a first film pattern above a substrate; forming a plurality of second film patterns like sandwiching the first film pattern from both sides; forming a third film in such a way that an upper surface of the first film pattern and an upper surface and an exposed side surface of each of the plurality of second film patterns are coated with the third film; removing a portion of the third film until the upper surface of the first film pattern is exposed; removing, by a wet process, the first film pattern exposed after the portion of the third film is removed; and removing a remainder of the third film by a dry process after the first film pattern is removed.

### BRIEF DESCRIPTION OF THE DRAWINGS

FIG. 1 is a flow chart showing principal parts of a method for fabricating a semiconductor device in an embodiment 1;

FIG. 2A to FIG. 2D are process sectional views showing processes performed corresponding to the flow chart in FIG. 1;

FIG. 3A to FIG. 3D are process sectional views showing processes performed corresponding to the flow chart in FIG. 1;

FIG. 4A to FIG. 4D are process sectional views showing processes performed corresponding to the flow chart in FIG. 1;

FIG. 5A and FIG. 5B are conceptual diagrams comparing removal of a film pattern to be a core material by a technique according to the embodiment 1 and a conventional technique;

FIG. 6 is a flowchart showing principal parts of a method for fabricating a semiconductor device in an embodiment 2;

FIG. 7A to FIG. 7C are process sectional views showing processes performed corresponding to the flow chart in FIG. 6; and

FIG. 8A and FIG. 8B are process sectional views showing processes performed corresponding to the flow chart in FIG. 6.

### DETAILED DESCRIPTION OF THE INVENTION

### Embodiment 1

In the embodiment 1, a method for fabricating a semiconductor device in such a way that a film pattern should not fall will be described. The embodiment 1 will be described below using drawings.

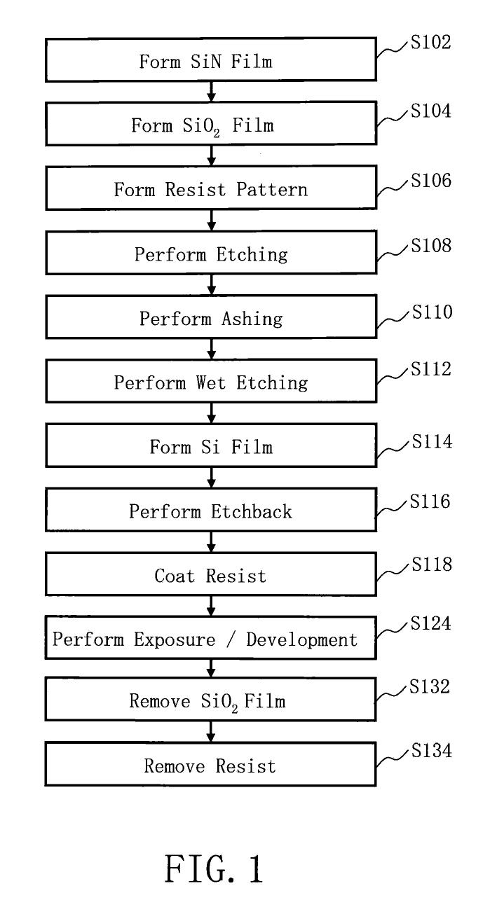

FIG. 1 is a flowchart showing principal parts of a method for fabricating a semiconductor device in the embodiment 1. In FIG. 1, the method for fabricating a semiconductor device in the embodiment 1 is a series of processes including an SiN film formation process (S102), an SiO₂ film formation process (S104), a resist pattern formation process (S106), an etching process (S108), an ashing process (S110), a wet etching process (S112), an Si film formation process (S114), an etch-back process (S116), a resist coating process (S118), an exposure/development process (S124), an SiO₂ film removal process (S132), and a resist removal process (S134).

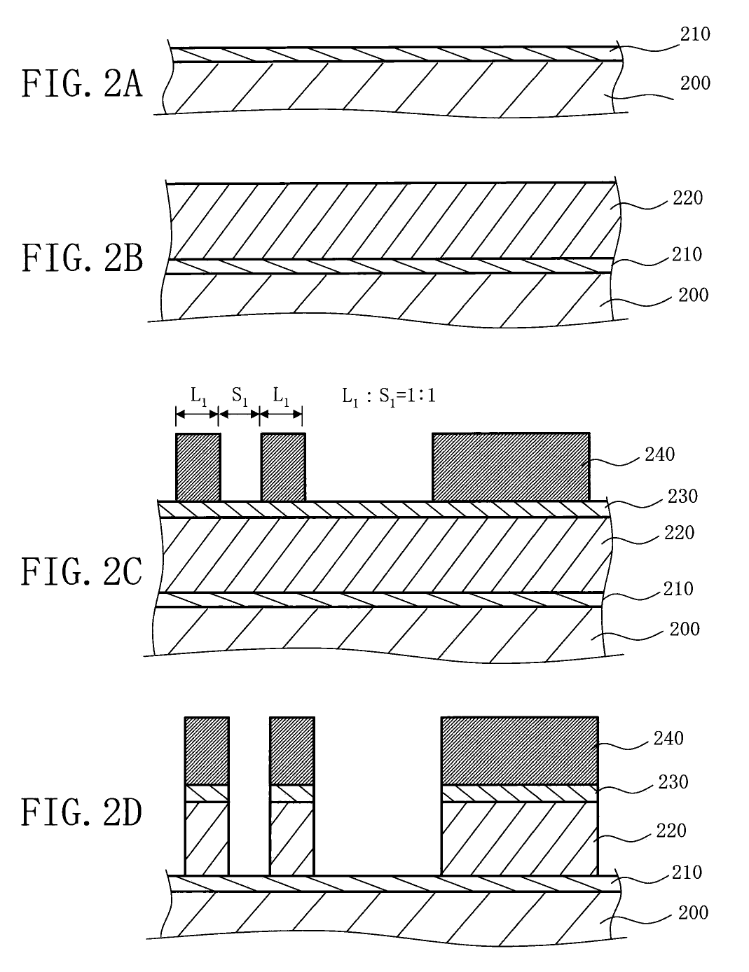

FIG. 2A to FIG. 2D are process sectional views showing processes performed corresponding to the flow chart in FIG. 1. FIG. 2A to FIG. 2D show the SiN film formation process (S102) to the etching process (S108) of FIG. 1.

In FIG. 2A, as the SiN film formation process (S102), a silicon nitride (SiN) film 210 to be a base film, or “ground film” is formed on the surface of a semiconductor substrate 200 by the CVD (chemical vapor deposition) method to a thickness of, for example, 50 nm. Here, the CVD method is used to form the film, but other methods may also be used. In addition to the SiN film, other materials containing Si like a silicon (Si) film, such as polysilicon or amorphous silicon, may also be used as a base film. A silicon wafer of 300 mm in diameter, for example, is used as the semiconductor substrate 200. A device portion or wires (not shown) may also be formed on the semiconductor substrate 200.

In FIG. 2B, as the SiO₂ film formation process (S104), an SiO₂ film 220 to be a sacrificial film (core material film) is formed on the surface of the SiN film 210 by the CVD method to a thickness of, for example, 150 nm.

In FIG. 2C, as the resist pattern formation process (S106), an antireflection film 230 is formed on the SiO₂ film 220 and a resist film 240 is coated to the antireflection film 230. A line & space pattern whose line (L1) width and space (S1) width are 1:1 is then exposed onto the resist in a region (minimum dimension portion) where a pitch of the minimum wire width and minimum space is required. At the same time, in the boundary region of the line (L1) & space (S1) pattern of pitch of the minimum wire width and minimum space, a pattern whose wire width is larger than the minimum dimension is exposed. A resist pattern in the top layer shown in FIG. 2C is then formed by performing development process. The dimension width of the line (L1) & space (S1) pattern is suitably set to the limit value of resolution of lithography technology in a region where the pitch is required to be formed with the minimum wire width and minimum space.

In FIG. 2D, as the etching process (S108), the antireflection film 230 and the SiO₂ film 220 are etched using the formed resist pattern as a mask and the SiN film 210 as an etching stopper.

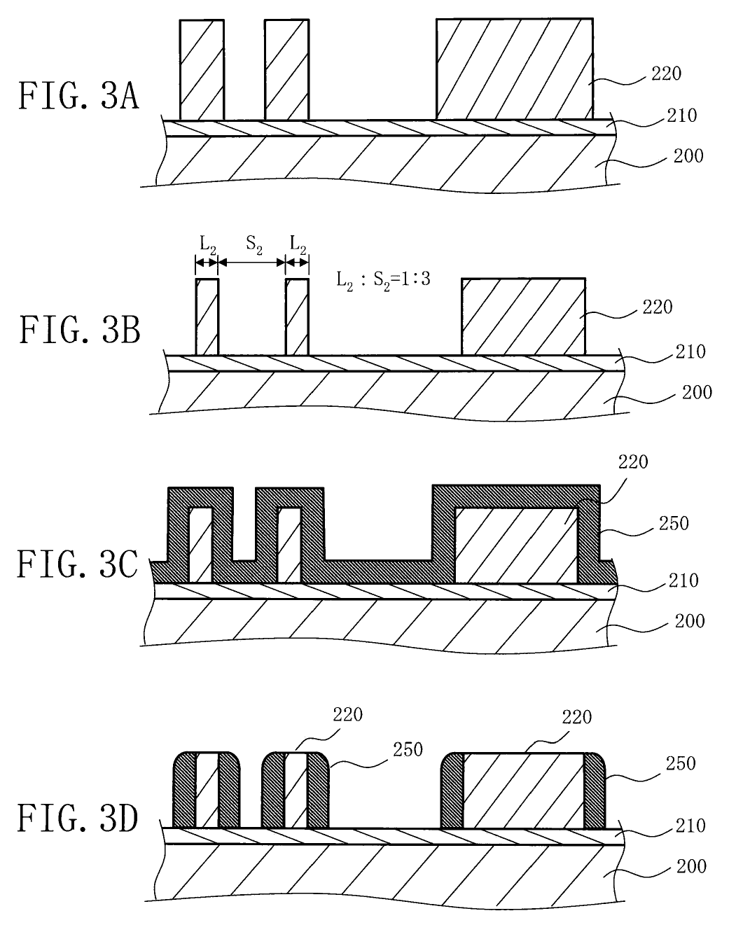

FIG. 3A to FIG. 3D are process sectional views showing processes performed corresponding to the flow chart in FIG. 1. FIG. 3A to FIG. 3D show the ashing process (S110) to the etch-back process (S116) of FIG. 1.

In FIG. 3A, as the ashing process (S110), the resist film 240 and the antireflection film 230 remaining after etching are removed by ashing and wet cleaning. A film pattern by the SiO₂ film 220 that makes the ratio of the line (L1) & space (S1) 1:1 in a minimum dimension portion is formed by the above process. In a boundary region, a film pattern of the SiO₂ film 220 with a wider width is formed.

In FIG. 3B, as the wet etching process (S112), the SiO₂ film 220 is etched by the wet etching method until the ratio of the line (L1) width and space (S1) width in a minimum dimension portion becomes 1:3. In this manner, a film pattern (first film pattern) of the SiO₂ film 220 is formed on the substrate 200. At this point, the film pattern of the SiO₂ film 220 can be made to have a width dimension narrower than the resolution limit of lithography.

In FIG. 3C, as the Si film formation process (S114), an Si film 250 is formed by depositing Si in such a way that the upper surface and the both side surfaces of the SiO₂ film 220 is coated with Si by using the CVD method. In this case, Si is deposited in such a way that the thickness of the Si film 250 is uniform (conforms). The thickness of the Si film 250 is of the order of the width dimension of the SiO₂ film 220. For example, amorphous silicon is suitably used as a material of the Si film 250. Here, if the aforementioned Si film is used instead of the SiN film 210 to be a base film, an SiN film is suitably used instead of the Si film 250.

In FIG. 3D, as the etch-back process (S116), the upper surface of the SiO₂ film 220 is etched back by the dry etching method. By the above process, as shown in FIG. 3D, a plurality of film patterns (second film patterns) of the Si film 250 sandwiching a film pattern of the SiO₂ film 220 from both sides is formed. Through the etch-back process, a film pattern of the SiO₂ film 220 is sandwiched by film patterns of the Si film 250 with the same width as that of the film pattern of the SiO₂ film 220 with a width dimension narrower than the resolution limit of lithography. The material of the film pattern of the SiO₂ film 220 and that of the film patterns of the Si film 250 contain Si.

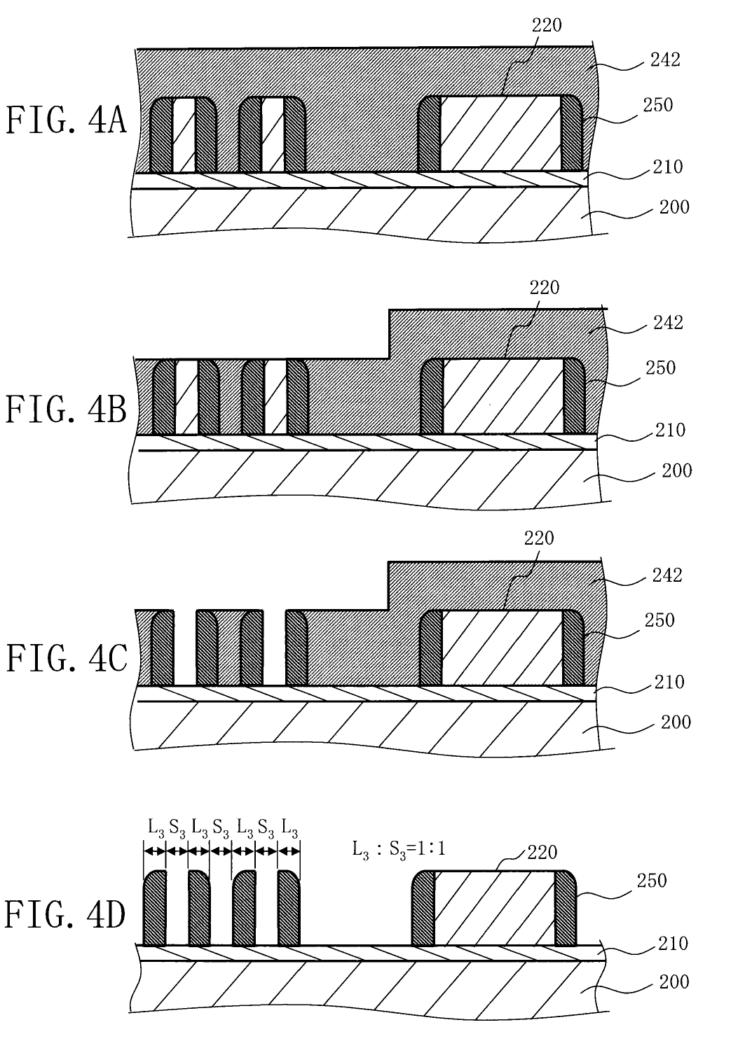

FIG. 4A to FIG. 4D are process sectional views showing processes performed corresponding to the flow chart in FIG. 1. FIG. 4A to FIG. 4D show the resist coating process (S118) to the resist removal process (S134) of FIG. 1.

In FIG. 4A, as the resist coating process (S118), a resist to be an organic material is coated to the substrate 200 to form a resist film 242 (third film) in such a way that the upper surface of the film patterns of the SiO₂ film 220 and the upper surface and the exposed side surface of the film patterns of the Si film 250 are coated with the resist. A positive type resist is suitably used as the resist material.

In FIG. 4B, as the exposure/development process (S124), the resist film 242 is exposed to light for development in such a way that the resist on a wider pattern portion formed in a boundary portion is not exposed to light. In this case, light exposure is adjusted so that the upper surface of the SiO₂ film 220 but nothing further beyond that is exposed to light. That is, light exposure is adjusted to underexposure conditions compared with exposure up to the bottom of the resist film 242. Then, a portion of the resist film 242 is removed to the position at which the upper surface of the film pattern of the SiO₂ film 220 in a dense pattern portion is exposed. The resist film 242 can be left on the upper surface side of the wider film pattern of the SiO₂ film 220 by the wider pattern portion not exposed to light. Moreover, by intentionally adjusting light exposure to underexposure conditions, the resist film 242 can be left between film patterns of the Si film 250 in a dense pattern portion of the minimum dimension portion.

In FIG. 4C, as the SiO₂ film removal process (S132), after a portion of the resist film 242 being removed, the exposed film patterns of the SiO₂ film 220 are removed by using the wet etching method. For example, a solution made to contain fluoric acid may be used as an etchant. Since the resist film 242 remains between film patterns of the Si film 250, the film patterns of the Si film 250 can be prevented from falling even if the wet process is used when the film patterns of the SiO₂ film 220 are removed. Moreover, the resist film 242 acts as a protective film to prevent the SiO₂ film 220 in the wider pattern portion from being removed as well. When the film patterns of the SiO₂ film 220 are removed by the dry etching method, a portion of the SiO₂ film 220 may remain on the side surface side thereof. However, the SiO₂ film 220 in the minimum dimension portion can be fully removed by the wet etching method.

In FIG. 4D, as the resist removal process (S134), after the film patterns of the SiO₂ film 220 in the minimum dimension portion being removed, a remainder of the remaining resist film 242 is removed by the dry etching method or the ashing method using at least one gas of oxygen, ammonia, and hydrogen.

With the above processes, a line & space pattern whose ratio of line (L3) width and space (S3) width that exceeds the resolution limit of lithography is 1:1 can be formed in a dense pattern portion of the minimum dimension portion. Then, at the same time, a broad film pattern in which the line width of the Si film 250 and that of the SiO₂ film 220 are matched can be formed in a broad pattern portion of a boundary region. Therefore, though not shown, by etching a ground material using a subsequently obtained pattern as a mask, such a pattern can be transferred to the SiN film 210 below the SiO₂ film 220 or further below thereof to the substrate 200.

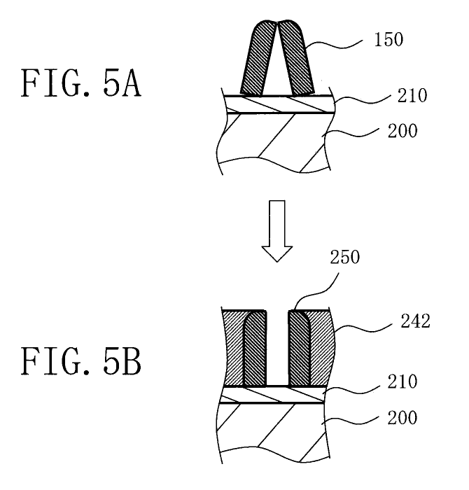

FIG. 5A and FIG. 5B are conceptual diagrams comparing the removal of a film pattern to be a core material by a technique according to the embodiment 1 and a conventional technique. When a film pattern to be a core material is removed by wet etching in the conventional technique, as shown in FIG. 5A, film patterns 150 positioned on both sides of the film pattern to be a core material may fall. A force such as the surface tension of an etchant acts during wet etching while the film patterns 150 are in a non-symmetrical form likely to fall after the film patterns 150 being formed by etchback and an exposed upper corner (shoulder) being etched so that film patterns 150 without support on either side are expected to fall. In contrast, in the embodiment 1, as shown in FIG. 5B, the resist film 242 is arranged on the side surface side of the film patterns of the Si films 250, sandwiching the film pattern to be a core material and, therefore, the resist film 242 supports the Si films 250 from the side surface side so that the film patterns can be prevented from falling.

Here, in the example described above, the resist film 242 is used as a film to prevent the film patterns of the Si film 250 from falling, but the film for fall prevention is not limited to the resist film and a film containing carbon as a main component can be used. For example, a carbon film formed by the CVD method can be used. In addition, an organic material can be used. Any material that is not removed by wet etching when the film patterns of the SiO₂ film 220 are removed may be used. And, any material that is removable by a dry process such as the dry etching method and ashing method may be used. If, instead of the resist film 242, a material other than a resist material containing carbon as a main component is used, it may be difficult to remove the film containing carbon as a main component until the upper surface of the SiO₂ film 220 is exposed by the exposure/development process (S124) alone. Thus, in such cases, the film containing carbon as a main component may be etched until the upper surface of the SiO₂ film 220 is exposed by the dry etching method using at least one gas of oxygen, ammonia, and hydrogen.

If, instead of the SiO₂ film 220, a resist is used as a core material and, for example, an SiO₂ film is used as a film with which the core material is coated, it becomes difficult to form a film, as described below. It is assumed that an SiO₂ film is formed on the side surface side of a film pattern of the resist by the LP-CVD method and, in such cases, there will be no resist to be a core material at process temperature for forming the SiO₂ film. Thus, it becomes impossible in the first place to conformally deposit an SiO₂ film in such a way that the core material is coated with the SiO₂ film. Therefore, it is not preferable to use a resist as a core material in place of the SiO₂ film 220.

In the embodiment described above, when the core material in a dense pattern portion of the minimum dimension portion is removed, the resist film 242 acts as a protective film to prevent the core material in a wider pattern portion in a boundary region from being removed as well. However, if a resist is used as the core material in place of the SiO₂ film 220, the core material and the protective film to protect the core material will be made of the same material so that the core material in a wider pattern portion will be removed as well and cannot be protected. Also from this point, it is not preferable to use a resist as a core material in place of the SiO₂ film 220.

According to the embodiment 1 as described above, film patterns constituting the line portion of a line & space pattern can be prevented from falling.

### Embodiment 2

In the embodiment 1, a technique to reduce light exposure is used when a portion of the resist film 242 is removed up to a position at which the upper surface of the SiO₂ film 220 in a dense pattern portion of the minimum dimension portion is exposed. In the embodiment 2, a case in which another technique is used will be described.

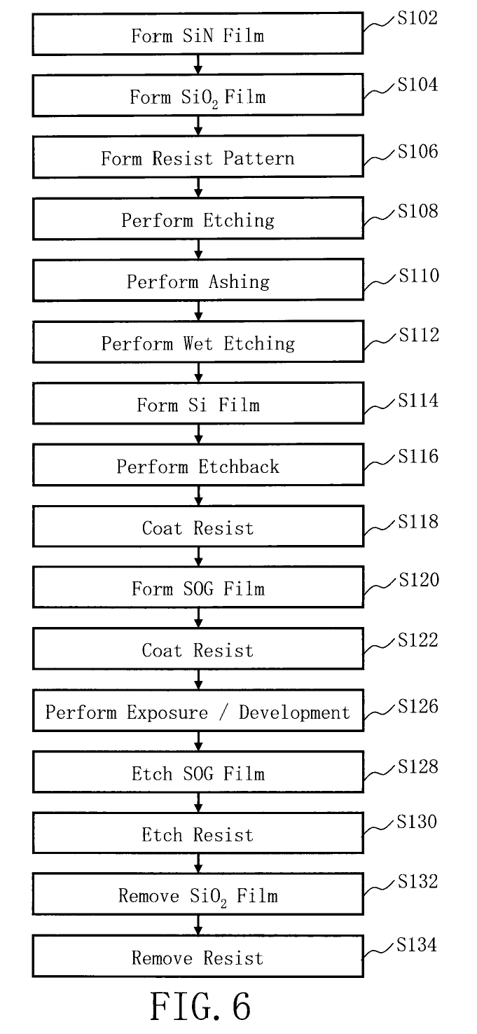

FIG. 6 is a flow chart showing principal parts of a method for fabricating a semiconductor device in the embodiment 2. FIG. 6 is the same as FIG. 1 except that an SOG (Spin on Glass) film formation process (S120), a resist coating process (S122), an exposure/development process (S126), an SOG film etching process (S128), and resist etching process (S130) are added in place of the exposure/development process (S124) in FIG. 1. Thus, the content of each process from the SiN film formation process (S102) to the resist coating process (S118) is the same as in the embodiment 1. Therefore, processes from the state shown in FIG. 4A will be described below.

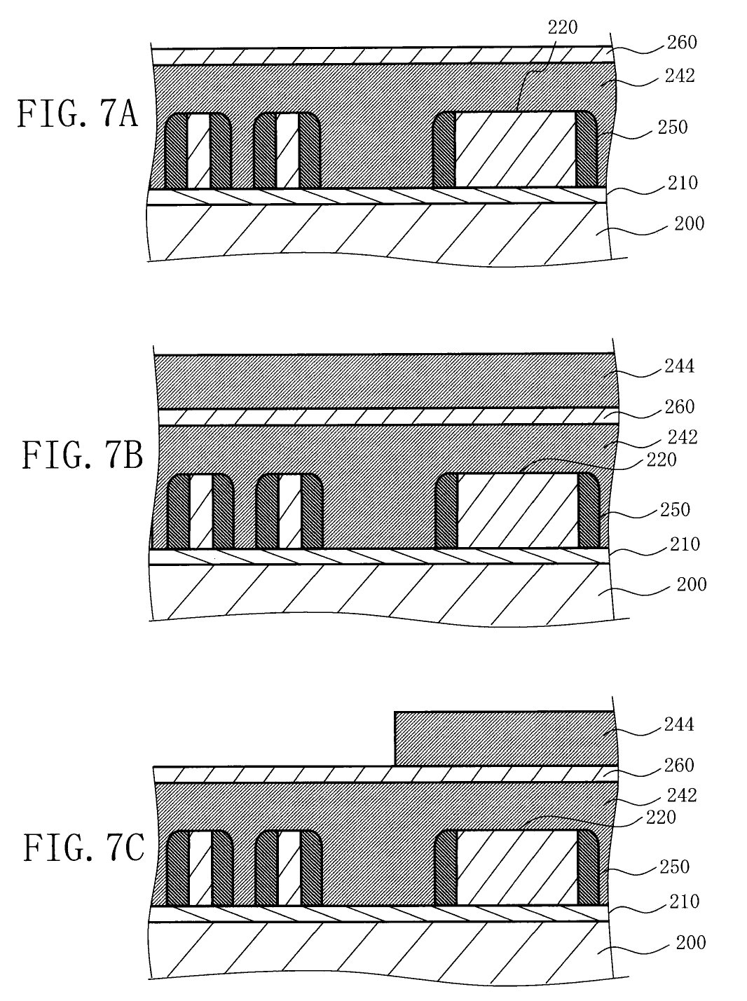

FIG. 7A to FIG. 7C are process sectional views showing processes performed corresponding to the flow chart in FIG. 6. FIG. 7A to FIG. 7C show the SOG film formation process (S120) to the exposure/development process (S126) of FIG. 6.

In FIG. 7A, as the SOG film formation process (S120), an SOG film 260 (fourth film) is formed on the resist film 242 using a spin coating method from the state shown in FIG. 4A.

In FIG. 7B, as the resist coating process (S122), a resist film 244 is formed on the SOG film 260 by coating a resist material.

In FIG. 7C, as the exposure/development process (S126), the resist film 244 is exposed to light for development in such a way that a wider pattern portion is not exposed to light. With the above process, the resist film 244 on the SOG film 260 in a dense pattern portion of the minimum dimension portion can be removed. A resist pattern (fifth film pattern) of the resist film 244 is selectively formed on the SOG film 260 positioned on the film patterns of the wider SiO₂ film 220 in a boundary region by the above process.

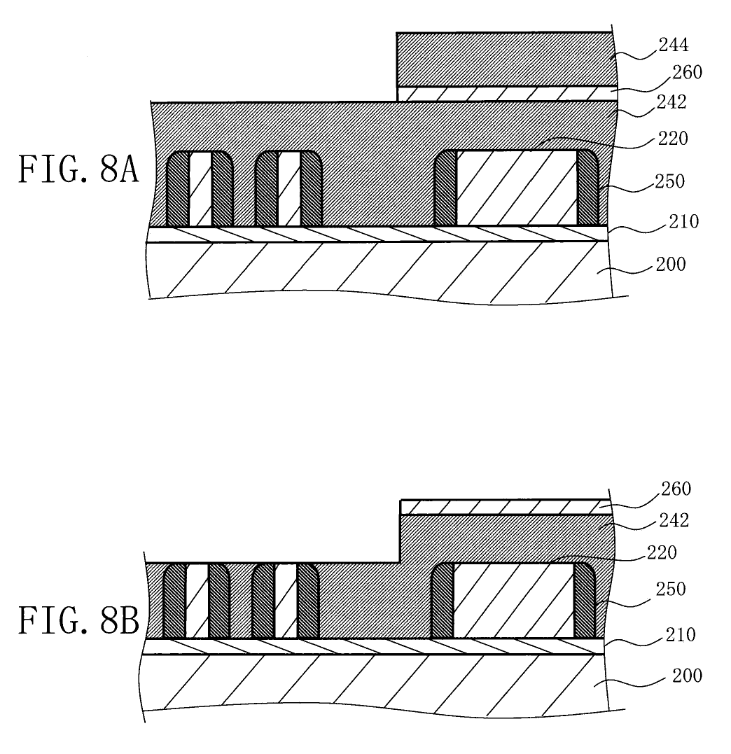

FIG. 8A and FIG. 8B are process sectional views showing processes performed corresponding to the flow chart in FIG. 6. FIG. 8A and FIG. 8B show the SOG film etching process (S128) and the resist etching process (S130) of FIG. 6.

In FIG. 8A, as the SOG film etching process (S128), the exposed SOG film 260 is etched by the dry etching method using a resist pattern of the remaining resist film 244 as a mask. A fluorocarbon gas, for example, may be used as an etching gas.

In FIG. 8B, as the resist etching process (S130), a portion of the resist film 242 is removed by etching the resist film 242 until the upper surface of the SiO₂ film 220 in a dense pattern portion of the minimum dimension portion is exposed by the dry etching method using at least one gas of oxygen, ammonia, and hydrogen. In this case, for example, the reactive ion etching (RIE) method that generates plasma may be used, and thus there is no need for the resist film 242 to have photosensitivity in the embodiment 2. Here, when dry etching is performed, the etching area changes with exposure of the upper surface of the SiO₂ film 220 so that the end point can be detected by monitoring plasma emission or plasma impedance. Thus, the resist film 242 can be left between the Si films 250 while causing the upper surface of the SiO₂ film 220 to be precisely exposed. When a portion of the resist film 242 is removed, the resist pattern of the resist film 244 is removed as well using the SOG film 260 remaining below the resist pattern by the resist film 244 as a stopper.

Here, if the etching area barely changes with exposure of the upper surface of the SiO₂ film 220 due to pattern relations, the end point is also suitably detected when the resist film 244 on the SOC film 260 disappears. In such cases, etching can precisely be stopped at the time of exposure of the upper surface of the SiO₂ film 220 by pre-adjusting the thickness of the resist film 244.

Next, as the SiO₂ film removal process (S132), after a portion of the resist film 242 being removed, the exposed film patterns of the SiO₂ film 220 are removed by using the wet etching method. For example, a solution made to contain fluoric acid may be used as an etchant. When the film patterns of the SiO₂ film 220 are removed by the wet etching method, the SOG film 260 used as a stopper can be removed as well. As a result, a state similar to that shown in FIG. 4C is reached. Since the resist film 242 remains between film patterns of the Si film 250, the film patterns of the Si film 250 can be prevented from falling when the film patterns of the SiO₂ film 220 are removed. Moreover, the resist film 242 acts as a protective film to prevent the SiO₂ film 220 in the wider pattern portion in a boundary region from being removed as well. Hereinafter, the resist removal process (S134) is the same as in the embodiment 1.

Also in the embodiment 2, as shown in FIG. 4D, a line & space pattern whose line (L3) width and space (S3) width are 1:1, exceeding the resolution limit of lithography, can be formed by each of the above processes in a dense pattern portion. At the same time, a broad film pattern in which the line width of the Si film 250 and that of the SiO₂ film 220 are matched can be formed.

Embodiments have been described with reference to concrete examples. However, the present invention is not limited to these concrete examples.

Though a description is omitted in the foregoing, the thickness of each layer, the number of layers and the size, shape, number and the like of patterns can be used by selecting what is needed for semiconductor integrated circuits and various semiconductor elements when necessary.

In addition, all semiconductor devices and methods for fabricating a semiconductor device that have elements of the present invention and whose design can be modified when necessary by persons skilled in the art are included in the scope of the present invention.

While techniques normally used in the semiconductor industry, for example, a photolithography process and cleaning before and after treatment are omitted for simplification of description, it is needless to say that such techniques are included in the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for fabricating a semiconductor device, comprising:
forming a first film pattern above a substrate;
forming a plurality of second film patterns like sandwiching the first film pattern from both sides;
forming a third film in such a way that an upper surface of the first film pattern and an upper surface and an exposed side surface of each of the plurality of second film patterns are coated with the third film;
removing a portion of the third film until the upper surface of the first film pattern is exposed;
removing, by a wet process, the first film pattern exposed after the portion of the third film is removed; and
removing a remainder of the third film by a dry process after the first film pattern is removed.

2. The method according to claim 1, wherein a material of the first film pattern and that of the plurality of second film patterns contain silicon (Si).

3. The method according to claim 2, wherein a silicon oxide (SiO₂) is used as the material of the first film pattern.

4. The method according to claim 2, wherein amorphous silicon is used as the material of the plurality of second film patterns.

5. The method according to claim 1, wherein the first film pattern is formed on a base film containing silicon (Si).

6. The method according to claim 5, wherein amorphous silicon is used as a material of the plurality of second film patterns and
silicon nitride (SiN) is used as a material of the base film.

7. The method according to claim 5, wherein silicon nitride (SiN) is used as a material of the plurality of second film pattern and
silicon is used as a material of the base film.

8. The method according to claim 1, wherein an organic material is used as a material of the third film.

9. The method according to claim 1, wherein when the first film pattern is formed, a plurality of first film patterns with different width dimensions is formed and
when the portion of the third film is removed, the portion of the third film is removed in such a way that the upper surface of the first film pattern with a narrower width is exposed and the third film remains on the first film pattern with a wider width.

10. The method according to claim 9, further comprising:
forming a fourth film on the third film before the portion of the third film is removed;
forming a fifth film pattern selectively on the fourth film positioned above the first film pattern with the wider width of the plurality of first film patterns; and
etching the fourth film exposed, by using the fifth film pattern as a mask, wherein
when the portion of the third film is removed, the fifth film pattern is removed as well using the fourth film remaining below the fifth film pattern as a stopper and
when the first film pattern is removed, the fourth film used as the stopper is removed as well.

11. The method according to claim 10, wherein an organic material is used as a material of the third film and the fifth film pattern and SOCG is used as a material of the fourth film.

12. The method according to claim 10, wherein the portion of the third film and the fifth film pattern are removed by a dry etching method using at least one gas of oxygen, ammonia, and hydrogen.

13. The method according to claim 1, wherein when the first film pattern is formed, a plurality of first film patterns in which a line dimension and a space dimension are substantially 1:1 is formed and etching is then performed until the line dimension and the space dimension are substantially 1:3 and
the plurality of second film patterns is formed like sandwiching the first film pattern whose the line dimension and the space dimension has been substantially changed to 1:3 from both sides.

14. The method according to claim 13, wherein a wet etching method is used as the etching.

15. The method according to claim 13, wherein the plurality of second film patterns is formed with a width substantially identical to that of the first film pattern.

16. The method according to claim 1, wherein when the plurality of second film patterns are formed, a second film is formed in such a way that the upper surface and exposed side surfaces of the first film pattern are conformally coated with the second film and the second film is etched into the plurality of second film patterns.

17. The method according to claim 9, wherein the third film is exposed to light in such a way that a lower part of the third film below the upper surface of the first film pattern and the third film on the first film pattern with the wider width are not exposed to light before the portion of the third film being removed.

18. The method according to claim 17, wherein the portion of the third film is removed by a development process in such a way that the upper surface of the first film pattern with the narrower width is exposed and the third film remains on the first film pattern with the wider width.

19. The method according to claim 1, wherein fluoric acid is used for the wet process.

20. The method according to claim 1, wherein a dry etching method using at least one gas of oxygen, ammonia, and hydrogen or an ashing method using at least one gas of oxygen, ammonia, and hydrogen is used for the dry process.
